(19) United States
(12) Patent Application Publication
(10) Pub. No.: US 2020/0171601 A1
(43) Pub. Date: Jun. 4, 2020

(54) LASER IRRADIATION DEVICE, METHOD OF MANUFACTURING THIN FILM TRANSISTOR, PROGRAM, AND PROJECTION MASK

(71) Applicant: V Technology Co., Ltd., Yokohama (JP)

(72) Inventors: Michinobu Mizumura, Yokohama (JP); Makoto Hatanaka, Yokohama (JP); Toshinari Arai, Yokohama (JP)

(21) Appl. No.: 16/782,369

(22) Filed: Feb. 5, 2020

Related U.S. Application Data
(63) Continuation of application No. PCT/JP2018/028087, filed on Jul. 26, 2018.

(30) Foreign Application Priority Data
Aug. 15, 2017 (JP) 2017-156968

(51) Int. Cl. B23K 26/06; B23K 26/073; B23K 26/066; H01L 21/02

(52) U.S. Cl. CPC B23K 26/0604; H01L 21/02532; B23K 26/066; B23K 26/0732

(57) ABSTRACT

A laser irradiation device includes a light source for generating a laser beam, a projection lens for irradiating a prescribed region of an amorphous silicon thin film deposited on a substrate with the laser beam, and a projection mask pattern that is disposed on the projection lens and that includes a rectangular transmission region for transmitting the laser beam in a prescribed projection pattern; and is characterized in that a short side of the rectangular transmission region has a length that causes the irradiation energy of the laser beam passing through the projection mask pattern to become substantially uniform in the prescribed region.

### TECHNICAL FIELD

This disclosure relates to forming of a thin film transistor and, more particularly, to a laser irradiation device for irradiating an amorphous silicon thin film with a laser beam to form a polysilicon thin film, a method of manufacturing a thin film transistor, a program, and a projection mask.

### BACKGROUND

As an inverted staggered thin film transistor, there is one in which an amorphous silicon thin film is used for a channel region. However, since an amorphous silicon thin film has a low electron mobility, there is a problem that a mobility of electric charge in a thin film transistor decreases when an amorphous silicon thin film is used for a channel region.

Therefore, there is a technique in which a prescribed region of an amorphous silicon thin film is poly-crystallized by being instantaneously heated by a laser beam to form a polysilicon thin film having a high electron mobility and the polysilicon thin film is used as a channel region.

For example, Japanese Unexamined Patent Application Publication No. 2016-100537 discloses that an amorphous silicon thin film is formed on a substrate, and then the amorphous silicon thin film is irradiated with a laser beam such as an excimer laser to be laser-annealed, thereby performing a process of melting and solidifying the amorphous silicon thin film in a short time to crystallize it into a polysilicon thin film. Japanese Unexamined Patent Application Publication No. 2016-100537 discloses that by performing this process, a channel region between a source and a drain of a thin film transistor can be formed by a polysilicon thin film having a high electron mobility, and thus an increase in operational speed of a transistor can be achieved.

In the thin film transistor disclosed in Japanese Unexamined Patent Application Publication No. 2016-100537, laser annealing is performed by radiating a laser beam to a portion serving as a channel region between a source and a drain. However, the intensity of the radiated laser beam may not be constant, and the degree of crystallization of polycrystalline silicon may be unequally biased in the channel region. In particular, when a laser beam is radiated via a projection mask, the intensity of the laser beam radiated to the portion serving as the channel region may not be constant due to a shape of the projection mask. As a result, the degree of crystallization in the portion serving as the channel region becomes biased.

For that reason, characteristics of the formed polysilicon thin film may not be uniform, which may cause a bias in characteristics of individual thin film transistors included in the substrate. As a result, there arises a problem that display unevenness occurs in a liquid crystal device manufactured using the substrate.

It could therefore be helpful to provide a laser irradiation device, a method of manufacturing a thin film transistor, a program, and a projection mask, in which a bias in characteristics of a laser beam radiated to a channel region can be reduced and variation in characteristics of a plurality of thin film transistors included in a substrate can be reduced.

### SUMMARY

Our laser irradiation device may include a light source which generates a laser beam, a projection lens which irradiates a prescribed region of an amorphous silicon thin film deposited on a substrate with the laser beam, and a projection mask pattern which is disposed on the projection lens and includes a rectangular transmission region transmitting the laser beam in a prescribed projection pattern, and is characterized in that a short side of the rectangular transmission region has a length which causes irradiation energy of the laser beam transmitted through the projection mask pattern to become substantially uniform in the prescribed region.

The laser irradiation device may be characterized in that the projection lens irradiates a plurality of prescribed regions on the substrate moving in a prescribed direction with the laser beam via the projection mask pattern, and the projection mask pattern is configured such that at least transmission regions adjacent to each other in one column orthogonal to the movement direction have different irradiation ranges on the prescribed regions from each other.

The laser irradiation device may be characterized in that the projection lens irradiates one of the prescribed regions with the laser beam using a plurality of transmission regions.

The laser irradiation device may be characterized in that the projection mask pattern is configured such that at least transmission regions adjacent to each other in one row in the movement direction have different irradiation ranges on the prescribed regions from each other.

The laser irradiation device may be characterized in that the projection mask pattern is configured such that a width or a size of the transmission region is determined on the basis of energy of the laser beam in the prescribed region.

The laser irradiation device may be characterized in that the projection lens is a plurality of microlenses included in a microlens array which can separate the laser beam, and each of a plurality of openings on masks included in the projection mask pattern corresponds to one of the plurality of microlenses.

Our laser irradiation method may include a generation step of generating a laser beam; a transmission step of transmitting the laser beam using a prescribed projection pattern via a projection mask pattern which is disposed on a projection lens and includes a rectangular transmission region transmitting the laser beam in the prescribed projection pattern; and an irradiation step of irradiating a prescribed region of an amorphous silicon thin film deposited on a substrate with the laser beam transmitted through the prescribed projection pattern, and is characterized in that a short side of the rectangular transmission region has a length which causes irradiation energy of the laser beam transmitted through the projection mask pattern to become substantially uniform in the prescribed region.

Our non-transitory computer-readable storage medium storing a program may cause a computer to execute: a generation function of generating a laser beam; a transmission function of transmitting the laser beam using a prescribed projection pattern via a projection mask pattern which is disposed on a projection lens and includes a rectangular transmission region transmitting the laser beam in the prescribed projection pattern; and an irradiation function of irradiating a prescribed region of an amorphous silicon thin film deposited on a substrate with the laser beam transmitted through the prescribed projection pattern, and is characterized in that a short side of the rectangular transmission region has a length which causes irradiation energy of the laser beam transmitted through the projection mask pattern to become substantially uniform in the prescribed region.

Our projection mask may be a projection mask disposed on a projection lens which radiates a laser beam generated from a light source, and is characterized in that the projection mask is provided with a rectangular transmission region to irradiate a prescribed region of an amorphous silicon thin film deposited on a substrate moving in a prescribed direction with the laser beam, and a short side of the rectangular transmission region has a length which causes irradiation energy of the laser beam transmitted through the transmission region to become substantially uniform in the prescribed region.

Our laser irradiation device, method of manufacturing a thin film transistor, program, and projection mask, in which a variation in characteristics of a laser beam radiated to a channel region can be reduced and unevenness in characteristics of a plurality of thin film transistors included in a substrate can be reduced, are provided.

### BRIEF DESCRIPTION OF THE DRAWINGS

FIG. 1 is a diagram showing a configuration of a laser irradiation device 10 according to a first example.

FIG. 2 is a diagram showing a configuration of a thin film transistor 20 of which a prescribed region has been subjected to an annealing process, according to the first example.

FIG. 3 is a diagram showing a configuration of a substrate 30 that the laser irradiation device 10 irradiates with a laser beam 14, according to the first example.

FIG. 4 is a diagram showing a configuration of a microlens array 13 according to the first example.

FIG. 5 is a diagram showing a configuration of a transmission region 151 included in the projection mask pattern 15.

FIG. 6 is a graph showing an energy state of the laser beam 14 in a channel region.

FIG. 7 is a diagram showing a configuration of the projection mask pattern 15 included in the projection mask pattern 15 according to the first example.

FIG. 8 is a graph showing an energy state of the laser beam 14 in the channel region according to the first example.

FIG. 9 is a diagram showing another configuration of the projection mask pattern 15 according to the first example.

FIG. 10 is a diagram showing another configuration of a transmission region 151A of the projection mask pattern 15 according to a second example.

FIG. 11 is a diagram showing a configuration of the projection mask pattern 15 according to the second example.

FIG. 12 is a diagram showing a configuration of the projection mask pattern 15 according to a third example.

FIG. 13 is a graph showing an energy state of the laser beam 14 in the channel region according to the third example.

FIG. 14 is a diagram explaining another configuration of the projection mask pattern 15 according to the third example.

FIG. 15 is a diagram explaining another configuration of the projection mask pattern 15 according to the third example.

FIG. 16 is a diagram showing a configuration of a laser irradiation device 10 according to a fourth example.

### DESCRIPTION OF REFERENCES

10 Laser irradiation device
11 Laser light source
12 Coupling optical system
13 Microlens array
14 Laser beam
15 Projection mask pattern
151, 151A Transmission region
17 Microlens
18 Projection lens
20 Thin film transistor
21 Amorphous silicon thin film
22 Polysilicon thin film
23 Source
24 Drain
30 Substrate

### DETAILED DESCRIPTION

Hereinafter, examples will be specifically described with reference to the accompanying drawings.

### First Example

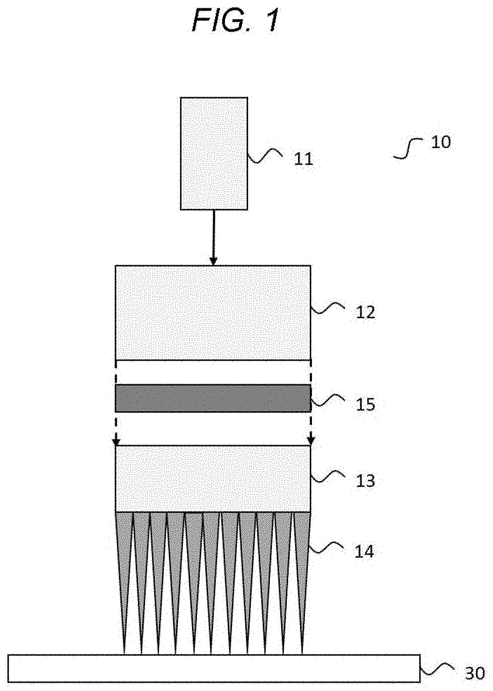

FIG. 1 is a diagram showing a configuration of a laser irradiation device 10 according to a first example.

The laser irradiation device 10 according to the first example is, for example, a device for laser irradiating (annealing) and recrystallizing a reserved channel-region with a laser beam 14 in a process of manufacturing a semiconductor device such as a thin film transistor (TFT) 20.

The laser irradiation device 10 is used, for example, when forming a thin film transistor of a pixel such as a peripheral circuit of a liquid crystal display device. In forming such a thin film transistor, first, a gate electrode made of a metal film such as an Al film is formed in a pattern on a substrate 30 by sputtering. Then, a gate insulating film made of a SiN film is formed on the entire surface of the substrate 30 using a low-temperature plasma chemical vapor deposition (CVD) method. Thereafter, an amorphous silicon thin film 21 is formed on the gate insulating film by, for example, a plasma CVD method. That is, the amorphous silicon thin film 21 is formed (deposited) on the entire surface of the substrate 30. Finally, a silicon dioxide (SiO₂) film is formed on the amorphous silicon thin film 21. Then, a prescribed region of the amorphous silicon thin film 21 on the gate electrode is irradiated and annealed with the laser beam 14 using the laser irradiation device 10 illustrated in FIG. 1 so that the prescribed region is poly-crystallized into polysilicon. Also, the substrate 30 may not necessarily be made of a glass material and may be a substrate of any material such as a resin substrate formed of a material such as a resin. Although a glass substrate 30 will be described below as an example, the substrate 30 may be a substrate formed of another material such as a resin substrate.

As shown in FIG. 1, in the laser irradiation device 10, a beam system of the laser beam emitted from a laser light source 11 is expanded by a coupling optical system 12, and a luminance distribution thereof is made uniform. The laser light source 11 is, for example, an excimer laser that emits the laser beam 14 having a wavelength such as 308 nm and 248 nm at a prescribed repetition cycle.

Then, the laser beam 14 passes through a plurality of openings (transmission regions 151) of a projection mask pattern 15 provided on a microlens array 13 to be separated into a plurality of laser beams 14, which are radiated to a prescribed region of the amorphous silicon thin film 21. The projection mask pattern 15 is provided on the microlens array 13, and the prescribed region is irradiated with the laser beam 14 using the projection mask pattern 15. Then, the prescribed region of the amorphous silicon thin film 21 is instantaneously heated and melted, and a part of the amorphous silicon thin film 21 becomes a polysilicon thin film 22. Also, the projection mask pattern 15 may be called a projection mask.

The polysilicon thin film 22 has an electron mobility higher than that of the amorphous silicon thin film 21 and is used as a channel region for electrically connecting a source 23 and a drain 24 in a thin film transistor 20. Also, although an example in which the microlens array 13 is used has been shown in the example of FIG. 1, the microlens array 13 may not necessarily be used and the laser beam 14 may be radiated using one projection lens. Further, in the first example, when the polysilicon thin film 22 is formed using the microlens array 13 will be described as an example.

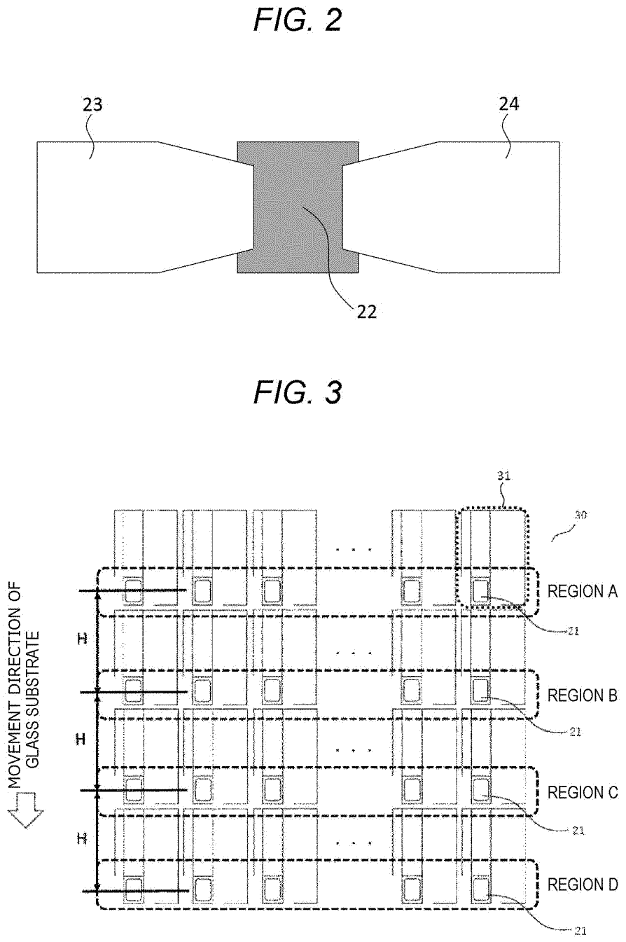

FIG. 2 is a diagram showing an example of the thin film transistor 20 in which the prescribed region has been subjected to an annealing process. Further, the thin film transistor 20 is formed by first forming the polysilicon thin film 22 and then forming the source 23 and the drain 24 at both ends of the formed polysilicon thin film 22.

In the thin film transistor shown in FIG. 2, at least one polysilicon thin film 22 is formed between the source 23 and the drain 24 as a result of the laser annealing. In addition, the laser irradiation device 10 irradiates one thin film transistor 20 with the laser beam 14 using, for example, twenty microlenses 17 included in one column (or one row) of the microlens array 13. That is, the laser irradiation device 10 irradiates one thin film transistor 20 with twenty shots of the laser beam 14. As a result, in the thin film transistor 20, the prescribed region of the amorphous silicon thin film 21 is instantaneously heated and melted to form the polysilicon thin film 22. Further, in the laser irradiation device 10, the number of microlenses 17 included in one column (or one row) of the microlens array 13 is not limited to twenty and may be any number as long as it is plural.

FIG. 3 is a diagram showing an example of the substrate 30 that the laser irradiation device 10 irradiates with the laser beam 14. Also, although the substrate 30 is, for example, a glass substrate, the substrate 30 may not necessarily be a glass material and may be a substrate of any material such as a resin substrate formed of a material such as a resin. As shown in FIG. 3, the substrate 30 includes a plurality of pixels 31, and each of the pixels 31 includes the thin film transistor 20. The thin film transistor 20 performs light transmission control in each of the plurality of pixels 31 by electrically turning on/off. In addition, before the annealing process is performed, the amorphous silicon thin film 21 is provided on the entire surface of the substrate 30. The prescribed region of the amorphous silicon thin film 21 is a region that becomes the channel region of the thin film transistor 20 via annealing and other processes.

The laser irradiation device 10 irradiates the prescribed region of the amorphous silicon thin film 21 with the laser beam 14. The laser irradiation device 10 radiates the laser beam 14 at a prescribed cycle, moves the substrate 30 at a time when the laser beam 14 is not radiated, and then irradiates a region of the next amorphous silicon thin film 21 with the laser beam 14. As shown in FIG. 3, the amorphous silicon thin film 21 is disposed on the entire surface of the substrate 30. Then, the laser irradiation device 10 radiates the laser beam 14 to the prescribed region of the amorphous silicon thin film 21 disposed (formed or deposited) on the substrate 30 at a prescribed cycle.

First, the laser irradiation device 10 irradiates a region A in FIG. 3 of the amorphous silicon thin film 21 provided (deposited) on the entire surface of the substrate 30 with the laser beam 14 using a first microlens 17 included in the microlens array 13. Thereafter, the substrate 30 is moved a prescribed interval “H.” While the substrate 30 is moving, the laser irradiation device 10 stops radiation of the laser beam 14. Then, after the substrate 30 is moved the interval “H,” the laser irradiation device 10 irradiates a region B in FIG. 3 of the amorphous silicon thin film 21 provided (deposited) on the entire surface of the substrate 30 with the laser beam 14 using a second microlens 17 included in the microlens array 13. In this example, the region A in FIG. 3 of the amorphous silicon thin film 21 provided (deposited) on the entire surface of the substrate 30 is irradiated with the laser beam 14 using the second microlens 17 adjacent to the first microlens 17 in the microlens array 13. As described above, the prescribed region of the amorphous silicon thin film 21 provided (deposited) on the entire surface of the substrate 30 is irradiated with the laser beam 14 using a plurality of microlenses 17 corresponding to one column (or one row) of the microlens array 13.

Also, after the substrate 30 is moved the interval “H,” the laser irradiation device 10 may irradiate the substrate 30 that has been temporarily stopped with the laser beam 14 and may irradiate the substrate 30 that is moving with the laser beam 14.

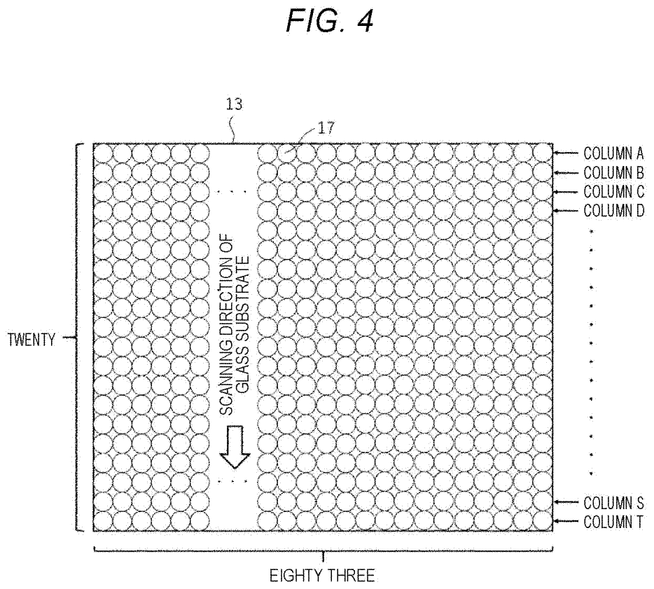

FIG. 4 is a diagram showing a configuration of the microlens array 13. As shown in FIG. 4, the laser irradiation device 10 irradiates the prescribed region of the amorphous silicon thin film 21 with the laser beam 14 by sequentially using the plurality of microlenses 17 included in the microlens array 13, and forms the prescribed region into the polysilicon thin film 22. As illustrated in FIG. 4, the number of microlenses 17 included in one column (or one row) of the microlens array 13 is twenty. For this reason, the prescribed region of the amorphous silicon thin film 21 formed (deposited) on the substrate 30 is irradiated with the laser beam 14 using the twenty microlenses 17. Further, the number of microlenses 17 included in one column (or one row) of the microlens array 13 is not limited to twenty and may be any number. Also, the number of microlenses 17 included in one row (or one column) of the microlens array 13 is not limited to the eighty-three illustrated in FIG. 4 and may be any number.

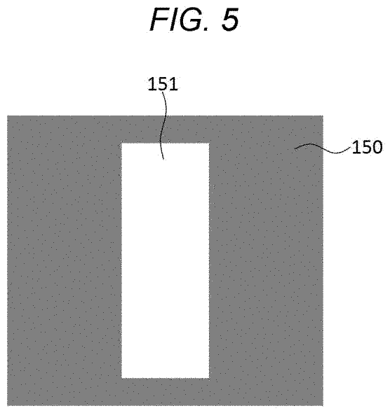

FIG. 5 is a configuration of a transmission region 151 included in the projection mask pattern 15. The projection mask pattern 15 corresponds to the microlenses 17 included in the microlens array 13. In the example of FIG. 5, the projection mask pattern 15 includes a transmission region 151. The laser beam 14 passes through the transmission region 151 of the projection mask pattern and is radiated to a portion that becomes the channel region of the thin film transistor 20 (that is, the prescribed region of the amorphous silicon thin film 21 formed (deposited) on the substrate 30). The transmission region 151 of the projection mask pattern 15 has a width (a length of a short side) of about 50 μm. Also, the length of the width is merely an example and may be any length. In addition, a length of a long side of the transmission region 151 of the projection mask pattern 15 is, for example, about 100 μm. Also, the length of the long side is merely an example and may be any length.

Further, the microlens array 13 irradiates the projection mask pattern 15 by reducing it to, for example, ⅕. As a result, the laser beam 14 transmitted through the projection mask pattern 15 is reduced to a width of about 10 μm in the channel region. In addition, the laser beam 14 transmitted through the projection mask pattern 15 is reduced to a length of about 20 μm in the channel region. Also, a reduction ratio of the microlens array 13 is not limited to ⅕ and may be any scale. Further, the projection mask pattern 15 is formed by arranging the projection mask pattern 15 illustrated in FIG. 5 as many as at least the number of microlenses 17.

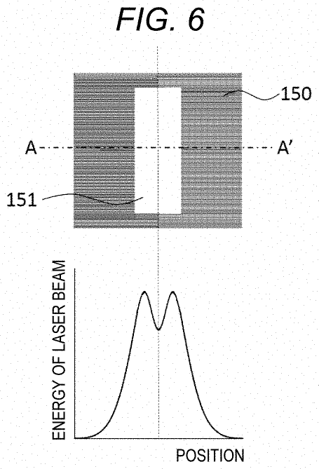

FIG. 6 is a graph showing an energy state of the laser beam 14 in the channel region when the laser beam 14 is radiated using the projection mask pattern 15 illustrated in FIG. 5. In the graph of FIG. 6, a horizontal axis is a position, and a vertical axis is energy of the laser beam 14 (energy in the portion that becomes the channel region). In addition, the energy state illustrated in FIG. 6 is an energy state (energy intensity distribution) in a cross-sectional view of a central portion (line A-A′ in FIG. 6) in the channel region. Also, the example of FIG. 6 is merely an example, and it is needless to say that the energy state (energy intensity distribution) of the laser beam 14 in the channel region changes depending on energy when the laser beam 14 is radiated, a size of the projection mask pattern 15 or the like.

As shown in FIG. 6, in a region that becomes the channel region, it can be understood that energy of the laser beam 14 transmitted through a peripheral portion (an edge portion) of the projection mask pattern 15 is higher than energy of the laser beam 14 transmitted through other portions (that is, there is a peak). When energy radiated by the laser beam 14 is high, a rate at which crystal grows (a rate at which a size of polysilicon crystal increases) in the amorphous silicon thin film 21 increases. That is, in the peripheral portion (edge portion) of the portion that becomes the channel region, the rate at which the crystal grows (the rate at which the size of the polysilicon crystal increases) becomes faster than those of the other portions.

For this reason, since a degree of crystallization of the polysilicon crystal is unequally biased in the portion that becomes the channel region, characteristics of the formed polysilicon thin film are not uniform, and thus a bias in characteristics of each thin film transistor 20 included in the substrate 30 occurs. As a result, a problem arises in that display unevenness occurs in a liquid crystal device manufactured using the substrate 30.

Therefore, in the projection mask pattern 15 according to the first example, by shortening the width of the projection mask pattern 15, irradiation energy of the laser beam 14 transmitted through the peripheral portion (edge portion) of the projection mask pattern 15 is prevented from increasing. This prevents the rate at which the crystal grows (the rate at which the size of the polysilicon crystal increases) in the peripheral portion (edge portion) of the portion that becomes the channel region from becoming faster than those of other portions so that the degree of crystallization of the polysilicon crystal is not unequally biased in the portion that becomes the channel region. As a result, the characteristics of the polysilicon thin film to be formed can be made uniform, and occurrence of display unevenness in a liquid crystal device manufactured using the substrate can be prevented.

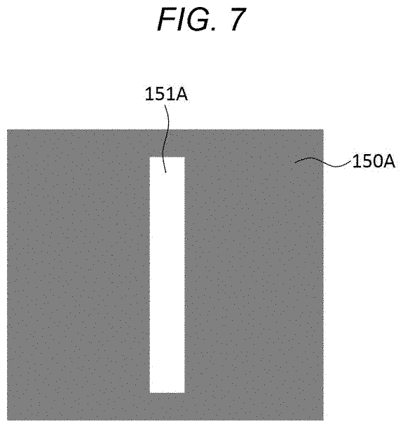

FIG. 7 is a schematic diagram showing a configuration of the projection mask pattern 15 according to the first example. As shown in FIG. 7, a width of a transmission region 151A of the projection mask pattern 15 is shorter than that of the transmission region 151 of the projection mask pattern 15 shown in FIG. 5. In the first example, the width of the transmission region 151A is, for example, 12 μm. This width is about ¼ of the transmission region 151 of the projection mask pattern 15 shown in FIG. 6. Also, the width of the transmission region 151 is not limited to 12 μm and may be any length as long as the irradiation energy of the laser beam 14 transmitted through the peripheral portion (edge portion) of the projection mask pattern 15 does not increase. In addition, a length of a long side (a longer side) of the transmission region 151A is about 100 μm.

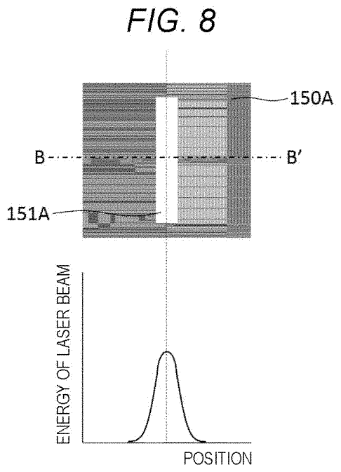

FIG. 8 is a graph showing an energy state (energy intensity distribution) of the laser beam 14 in the portion that becomes the channel region when the laser beam 14 is radiated using the projection mask pattern 15 including the transmission region 151A. In the graph of FIG. 8, a horizontal axis is a position, and a vertical axis is energy of the laser beam 14. In addition, the energy state illustrated in FIG. 8 is an energy state (energy intensity distribution) in a cross-sectional view of a central portion (line B-B′ in FIG. 6) in the channel region. Also, the example of FIG. 8 is merely an example, and it is needless to say that, similarly to FIG. 6, the energy state (energy intensity distribution) of the laser beam 14 in the channel region changes depending on energy when the laser beam 14 is radiated, a size of the projection mask pattern 15 or the like.

As shown in FIG. 8, in the region that becomes the channel region, it can be understood that the energy of the laser beam 14 transmitted through the projection mask pattern 15 including the transmission region 151A is different from the energy illustrated in FIG. 6 and does not cause a phenomenon in which it becomes higher than energy of the laser beam 14 transmitted through other portions (that is, there is a peak). That is, the energy of the laser beam 14 transmitted through the projection mask pattern 15 including the transmission region 151A does not become larger at the edge portion of the projection mask pattern 15 than at other portions. That is, by using the projection mask pattern 15 including the transmission region 151A, the energy of the laser beam 14 radiated to the portion that becomes the channel region is made uniform. As a result, the laser beam 14 with uniform energy can be radiated to the portion that becomes the channel region so that the degree of crystallization of the polysilicon crystal is made uniform. For that reason, unevenness in characteristics of a plurality of thin film transistors included in the substrate 30 can be reduced.

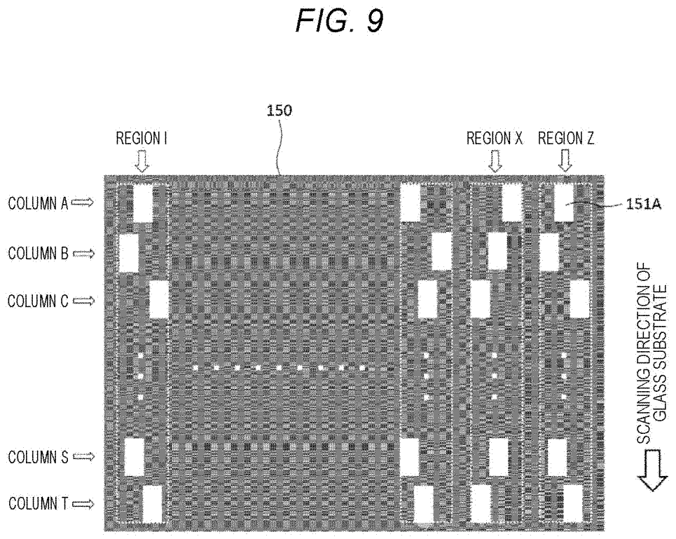

FIG. 9 is a diagram showing a configuration of the projection mask pattern 15. As shown in FIG. 9, the projection mask pattern 15 is provided with the transmission regions 151A to correspond to each of the microlenses 17 included in the microlens array 13 illustrated in FIG. 2. For example, in the projection mask pattern 15, twenty transmission regions 151A are provided in one row (that is, a region I or a region X).

Further, as shown in FIG. 9, in one column of the projection mask pattern 15 (for example, a column A or a column B), at least transmission regions 151A adjacent to each other have positions different from each other. For example, in FIG. 9, positions of the transmission regions 151A in the region X and a region Z adjacent to each other in the column A are different from each other. Also, in FIG. 9, positions of the transmission regions 151A in the region X and the region Z adjacent to each other in the column B are different from each other. Therefore, in the projection mask pattern 15, at least the transmission regions 151A adjacent to each other have different irradiation ranges with respect to prescribed regions of the amorphous silicon thin film 21 formed (deposited) on the substrate 30.

Also, the projection mask pattern 15 illustrated in FIG. 9 is merely an example, and the position of the transmission region 151A in the projection mask pattern 15 may be provided at any position. In addition, in the projection mask pattern 15, at least the transmission regions 151A adjacent to each other may have the same positions.

Also, as illustrated in FIG. 9, in one row of the projection mask pattern 15 (for example, the region I in FIG. 9), positions of the transmission regions 151A in columns adjacent to each other (for example, the column A and the column B in the region I) may be different from each other. For example, in FIG. 9, positions of the transmission regions 151A in the column B and a column C of the region Z may be different from each other.

Further, in one row of the projection mask pattern 15 (the region I or the region X in FIG. 9), a total area of the twenty transmission regions 151A is preferably set to a prescribed value (a prescribed area). That is, the total area of the transmission regions 151A in the columns A to T of the region I of the projection mask pattern 15 illustrated in FIG. 9 and the total area of the transmission regions 151A in the columns A to T of the region X are all set to be a prescribed value (a prescribed area). As a result, no matter which “row” of the projection mask pattern 15 is used, a total of irradiation areas of the laser beam 14 radiated to the portion that becomes the channel region (that is, the prescribed region of the amorphous silicon thin film 21 formed (deposited) on the substrate 30) of the thin film transistor 20 becomes constant. Also, in one row of the projection mask pattern 15 (the region I or the region X in FIG. 9), the total area of the twenty transmission regions 151A may not necessarily be set to a prescribed value (a prescribed area), and the irradiation area of the laser beam 14 may be different for each “row.”

In the example of FIG. 9, the transmission region 151A of the projection mask pattern 15 is provided to be orthogonal to a movement direction (a scanning direction) of the substrate 30. Also, the transmission region 151A of the projection mask pattern 15 may not necessarily be orthogonal to the movement direction (scanning direction) of the substrate 30 and may be provided parallel (substantially parallel) to the movement direction (scanning direction).

The laser irradiation device 10 irradiates the substrate 30 illustrated in FIG. 3, on the entire surface of which the amorphous silicon thin film is provided (deposited), with the laser beam 14 using the projection mask pattern 15 shown in FIG. 9. As a result, in the substrate 30 illustrated in FIG. 3, for example, the region X is irradiated with the laser beam 14 using the twenty microlenses 17 masked by the columns A to T of the region X illustrated in FIG. 9. On the other hand, the region Z adjacent thereto is irradiated with the laser beam 14 using twenty microlenses 17 masked by the columns A to T of the region Z illustrated in FIG. 9. As a result, in regions in the scanning direction (that is, the region X and the region Z) on the substrate 30 illustrated in FIG. 4, the thin film transistors 20 in the regions adjacent to each other are irradiated with the laser beam 14 using the microlenses 17 in different columns from each other. For this reason, in the regions in the scanning direction (that is, the region X and the region Z) on the substrate 30 illustrated in FIG. 4, the thin film transistors 20 in the regions adjacent to each other have different characteristics from each other.

Next, a method of manufacturing the thin film transistor 20 according to the first example illustrated in FIG. 2 using the laser irradiation device 10 will be described.

First, the laser irradiation device 10 irradiates the region that becomes the channel region (the region to be the channel region, that is, the prescribed region of the amorphous silicon thin film 21 formed (deposited) on the substrate 30) of the thin film transistor 20 with the laser beam 14 using one microlens 17 assigned to the projection mask pattern 15 including the projection mask pattern 15 illustrated in FIG. 9. As a result, the amorphous silicon thin film 21 provided in the region that becomes the channel region of the thin film transistor 20 (the region to be the channel region) is instantaneously heated and melted to become the polysilicon thin film 22.

The substrate 30 is moved a prescribed distance each time the laser beam 14 is radiated using one microlens 17. The prescribed distance is a distance “H” between the plurality of thin film transistors 20 on the substrate 30 as illustrated in FIG. 3. The laser irradiation device 10 stops radiation of the laser beam 14 while the substrate 30 is moved the prescribed distance.

After the substrate 30 has moved the prescribed distance “H,” the laser irradiation device 10 again irradiates the channel region irradiated using the one microlens 17 with the laser beam 14 using another microlens 17 included in the microlens array 13. As a result, the amorphous silicon thin film 21 provided in the region that becomes the channel region (the region to be the channel region) of the thin film transistor 20 is instantaneously heated and melted to become the polysilicon thin film 22.

The above steps are repeated, and the region that becomes the channel region of the thin film transistor 20 (the region to be the channel region) is irradiated with the laser beam 14 for twenty shots sequentially using each of the twenty microlenses 17 assigned to the projection mask pattern 15. As a result, the polysilicon thin film 22 is formed in the prescribed region of the thin film transistor 20 on the substrate 30.

Then, in another step, the source 23 and the drain 24 are formed in the thin film transistor 20.

As described above, in the first example, by shortening the width of the projection mask pattern 15, the irradiation energy of the laser beam 14 transmitted through the peripheral portion (edge portion) of the projection mask pattern 15 is prevented from increasing. Thus, in the peripheral portion (edge portion) of the channel region, the rate at which the crystal grows (the rate at which the size of the polysilicon crystal increases) is prevented from being faster than those of other portions so that the degree of crystallization of the polysilicon crystal is not unequally biased in the region that becomes the channel region (in the region to be the channel region). As a result, characteristics of the polysilicon thin film to be formed can be made uniform, and occurrence of display unevenness in a liquid crystal device manufactured using the substrate 30 can be prevented.

### Second Example

A second example is an aspect of when the prescribed region (the region that becomes the channel region in the thin film transistor 20) of the substrate 30 is irradiated with the laser beam via a plurality of transmission regions 151A. Thus, as compared to radiating the laser beam through one transmission region 151A as in the first example, an amount of the laser beam that can be radiated to the prescribed region of the amorphous silicon thin film 21 formed (deposited) on the substrate 30 increases and, therefore, the prescribed region can be efficiently annealed.

Since a configuration of the laser irradiation device 10 according to the second example is the same as the laser irradiation device 10 according to the first example illustrated in FIG. 1, a detailed description therefor will be omitted.

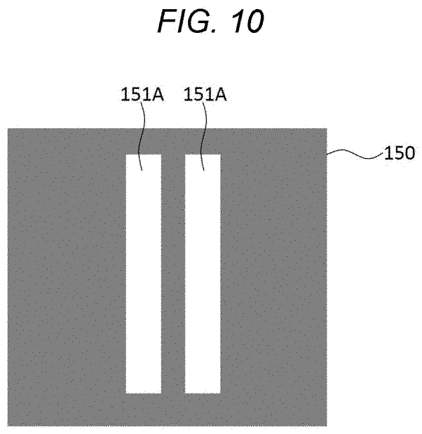

FIG. 10 is a schematic diagram showing a configuration of the projection mask pattern 15 according to the second example. The transmission regions 151A of the projection mask pattern 15 shown in FIG. 10 transmit the laser beam 14 radiated to the prescribed region of the amorphous silicon thin film 21 formed (deposited) on the substrate 30. That is, in the second example, the projection mask pattern 15 is provided with the plurality of transmission regions 151A that transmit the laser beam 14 radiated to the prescribed region of the amorphous silicon thin film 21. For example, as illustrated in FIG. 10, two transmission regions 151A for transmitting the laser beam 14 radiated to the prescribed region of the amorphous silicon thin film 21 are provided. Thus, as compared to when the laser beam 14 is radiated to the prescribed region of the amorphous silicon thin film 21 through one transmission region 151A, an amount of the laser beam 14 that can be radiated to the prescribed region of the amorphous silicon thin film 21 (the region that becomes the channel region in the thin film transistor 20) increases, and therefore the prescribed region can be efficiently annealed.

Further, in the second example, similarly to the first example, a width of the transmission region 151A is shorter than that of the transmission region 151 of the projection mask pattern 15 shown in FIG. 5. For that reason, the irradiation energy of the laser beam 14 transmitted through the peripheral portion (edge portion) of the projection mask pattern 15 does not increase, and in the peripheral portion (edge portion) of the region that becomes the channel region, the rate at which the crystal grows (the rate at which the size of the polysilicon crystal increases) is prevented from being faster than those of other portions so that the degree of crystallization of the polysilicon crystal is not unequally biased in the channel region. As a result, characteristics of the polysilicon thin film to be formed can be made uniform, and occurrence of display unevenness in a liquid crystal device manufactured using the substrate 30 can be prevented.

A width of the transmission region 151A is, for example, 12 μm. This width is about ⅕ of the transmission region 151 of the projection mask pattern 15 shown in FIG. 6. Also, the width of the transmission region 151 is not limited to 12 μm and may be any length as long as energy of the laser beam 14 transmitted through the peripheral portion (edge portion) of the projection mask pattern 15 does not increase. Further, a length of a long side (a longer side) of the transmission region 151A is about 100 μm.

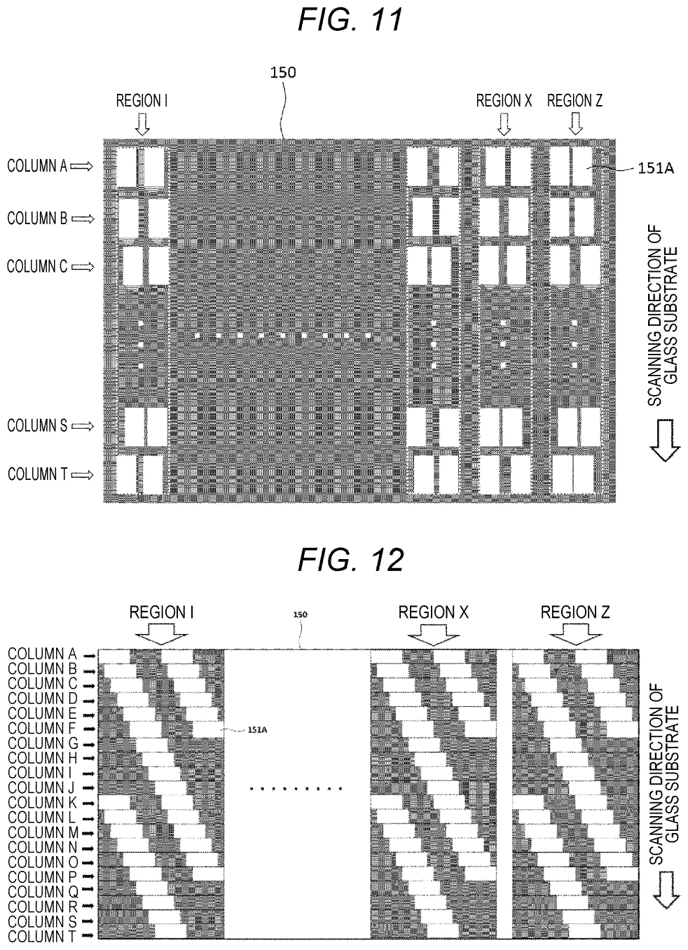

FIG. 11 is a diagram showing a configuration of the projection mask pattern 15 according to the second example. As shown in FIG. 11, the projection mask pattern 15 is provided with the transmission region 151A to correspond to each of the microlenses 17 included in the microlens array 13 illustrated in FIG. 2. For example, in the projection mask pattern 15, twenty transmission regions 151A are provided in one row (that is, the region I or the region X).

Further, as shown in FIG. 11, in one column (for example, a column A or column B) of the projection mask pattern 15, at least a plurality of transmission regions 151A adjacent to each other have arrangements different from each other. For example, in FIG. 11, arrangements of the transmission regions 151A in the region X and the region Z adjacent to each other in the column A are different from each other. In addition, in FIG. 11, arrangements of the transmission regions 151A in the region X and the region Z adjacent to each other in the column B are different from each other. Therefore, in the projection mask pattern 15, at least the transmission regions 151A adjacent to each other have different irradiation ranges with respect to prescribed regions of the amorphous silicon thin film 21 formed (deposited) on the substrate 30.

Also, the projection mask pattern 15 illustrated in FIG. 11 is merely an example, and the arrangement of the transmission regions 151A in the projection mask pattern 15 may be any arrangement. In addition, in the projection mask pattern 15, at least the transmission regions 151A adjacent to each other may have the same arrangements.

Also, as illustrated in FIG. 11, in one row (for example, the region I in FIG. 11) of the projection mask pattern 15, arrangements of a plurality of transmission regions 151A in columns (for example, the column A and the column B in the region I) adjacent to each other may be different from each other. For example, in FIG. 11, arrangements of the plurality of transmission regions 151A in the column B and the column C of the region Z may be different from each other.

Further, in one row of the projection mask pattern 15 (the region I or the region X in FIG. 11), a total area of the twenty transmission regions 151A is desirably set to be a prescribed value (a prescribed area). That is, the total area of the transmission regions 151A in the columns A to T of the region I of the projection mask pattern 15 illustrated in FIG. 11 and a total area of the transmission regions 151A in the columns A to T of the region X are all desirably set to be a prescribed value (a prescribed area). As a result, no matter which “row” of the projection mask pattern 15 is used, a total of the irradiation area of the laser beam 14 radiated to the amorphous silicon thin film 21 formed (deposited) on the substrate 30 becomes constant. Also, in one row (the region I or the region X in FIG. 11) of the projection mask pattern 15, the total area of the 20 transmission regions 151A may not necessarily be set to the prescribed value (prescribed area), and the irradiation area of 14 may be different for each “row.”

In the example of FIG. 11, the transmission region 151A of the projection mask pattern 15 is provided to be orthogonal to the movement direction (scanning direction) of the substrate 30. Also, the transmission region 151A of the projection mask pattern 15 may not necessarily be orthogonal to the movement direction (scanning direction) of the substrate 30 and may be provided parallel (substantially parallel) to the movement direction (scanning direction).

As described above, in the second example, the prescribed region (the region that becomes the channel region in the thin film transistor 20) of the amorphous silicon thin film 21 formed (deposited) on the substrate 30 is irradiated with the laser beam 14 via the plurality of transmission regions 151A. Therefore, since the prescribed region of the amorphous silicon thin film 21 can be irradiated with the laser beam 14 via the plurality of transmission regions 151A, an amount of the laser beam 14 that can be radiated to the prescribed region of the amorphous silicon thin film 21 increases, and thus the prescribed region can be efficiently annealed.

### Third Example

A third example is an aspect of when the transmission region 151A in the projection mask pattern 15 is formed in a prescribed pattern. Thus, in the third example, the transmission region 151A in the projection mask pattern 15 can be easily formed.

FIG. 12 is a diagram showing a configuration of the projection mask pattern 15 according to the third example. As shown in FIG. 12, the transmission region 151A is provided to correspond to each of the microlenses 17 included in the microlens array 13 illustrated in FIG. 2. For example, in the projection mask pattern 15, twenty transmission regions 151A are provided in one row (that is, the region I or the region X).

As illustrated in FIG. 12, in the projection mask pattern 15, the transmission regions 151A provided in one row (that is, the region I or the region X) are formed in a prescribed pattern (on the basis of a prescribed pattern). For example, as illustrated in FIG. 12, the prescribed pattern is a pattern in which, in the projection mask pattern 15, the transmission regions 151A provided in one row (that is, the region I or the region X) are provided to be shifted a prescribed length for each column (that is, the column A or the column B).

Specifically, the transmission region 151A in the column B of the region I is formed to be shifted a prescribed length in a direction perpendicular to the scanning direction of the substrate 30 from the transmission region 151A in the column A. Also, the transmission region 151A in the column C of the region I is formed to be shifted a prescribed length in the direction perpendicular to the scanning direction of the substrate 30 from the transmission region 151A in the column B. In this way, the transmission regions 151A are provided in the same prescribed pattern for each row of the projection mask pattern 15. In addition, the prescribed length is, for example, about 0.6 μm. Also, the prescribed length is not limited to about 0.6 μm and may be any length.

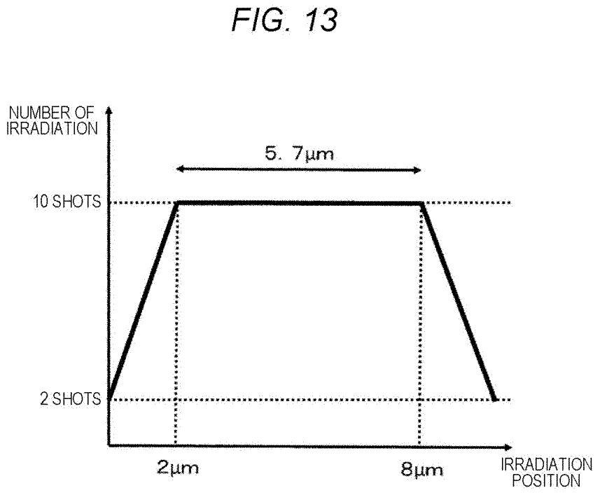

FIG. 13 is a graph showing the number of irradiations of the laser beam 14 in the channel region when the laser beam 14 is radiated using the projection mask pattern 15 including the transmission regions 151A illustrated in FIG. 12. Also, FIG. 13 shows the number of irradiations when the prescribed region of the amorphous silicon thin film 21 formed (deposited) on the substrate 30 is irradiated with the laser beam 14 using the transmission regions of all columns (twenty columns in the example of FIG. 12) included in the projection mask pattern 15. In the graph of FIG. 13, a horizontal axis is an irradiation position of the laser beam 14 in the channel region, and a vertical axis is the number of irradiations of the laser beam 14.

As shown in FIG. 13, in the channel region, the number of irradiations of the laser beam 14 transmitted through the projection mask pattern 15 including the transmission regions 151A illustrated in FIG. 12 are the same in the irradiation range having a width of 5.7 μm shown in FIG. 13. As illustrated in FIG. 13, the number of irradiations of the laser beam 14 transmitted through the projection mask pattern 15 illustrated in FIG. 12 is the same in the irradiation range having a width of 5.7 μm. Since the number of irradiations is the same, energy of the laser beam 14 radiated to the region that becomes the channel region (the region included in the irradiation range having a width of 5.7 μm) is made uniform.

Further, a width of the transmission region 151A is, for example, 12 μm. This width is about ¼ of the transmission region 151 of the projection mask pattern 15 shown in FIG. 6. In addition, a length of a long side (a longer side) of the transmission region 151A is about 100 μm.

Also, the width of the transmission region 151 is not limited to 12 μm and may be any length as long as the irradiation energy of the laser beam 14 transmitted through the peripheral portion (edge portion) of the projection mask pattern 15 does not increase.

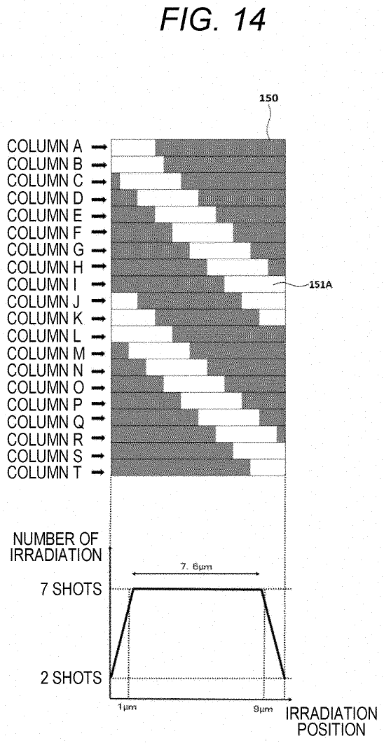

FIG. 14 is a diagram explaining the projection mask pattern 15 according to the third example. The upper portion of FIG. 14 shows another configuration of the projection mask pattern. As shown in the upper portion of FIG. 14, a width of the transmission region 151A is about 3.3 μm. In addition, in the upper portion of FIG. 14, the transmission regions 151A provided in one row (that is, the region I or the region X) are provided to be shifted a prescribed length for each column (that is, the column A or the column B). In the example of the upper portion of FIG. 14, the prescribed length is, for example, about 0.47 μm. Also, the prescribed length may be any length.

As illustrated in the upper portion of FIG. 14, in the projection mask pattern 15, the transmission regions 151A provided in one row (that is, the region I or the region X) has a width of 3.3 μm and have a pattern provided to be shifted a prescribed length of about 0.47 μm for each column (that is, the column A or the column B).

The lower portion of FIG. 14 is a graph showing the number of irradiations of the laser beam 14 in the region that becomes the channel region (the region to be the channel region) when the laser beam 14 is radiated using the projection mask pattern 15 including the transmission regions 151A illustrated in the upper portion of FIG. 14. Also, the lower portion of FIG. 14 shows the number of irradiations when the region that becomes the channel region of the thin film transistor 20 (the region to be the channel region) is irradiated with the laser beam 14 using the transmission regions of all the columns (twenty columns in the example of the upper portion of FIG. 14) included in the projection mask pattern 15. In the graph of the lower portion of FIG. 14, a horizontal axis is an irradiation position of the laser beam in the region that becomes the channel region (the region to be the channel region), and a vertical axis is the number of irradiations of the laser beam 14.

As shown in the lower portion of FIG. 14, the number of irradiations of the laser beam 14 transmitted through the projection mask pattern 15 including the transmission regions 151A is the same in the irradiation range having a width of 7.6 μm shown in the lower portion of FIG. 14. As illustrated in the lower portion of FIG. 14, the number of irradiations of the laser beam 14 transmitted through the projection mask pattern 15 illustrated in the upper portion of FIG. 14 is the same in the irradiation range having a width of 7.6 μm. Since the number of irradiations is the same, energy of the laser beam 14 radiated to the region that becomes the channel region (the region included in the irradiation range having a width of 7.6 μm) is made uniform.

### Modified Example

In the projection mask pattern 15, after the transmission regions 151A provided in one row (that is, the region I or the region X) are formed in the prescribed pattern illustrated in FIG. 12, they may be replaced at random.

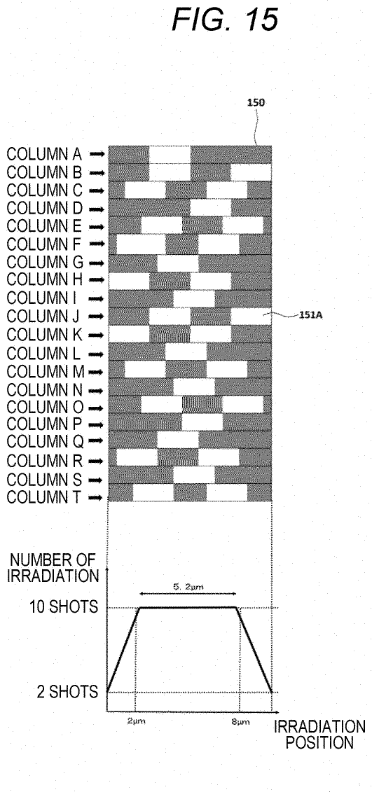

FIG. 15 is a diagram explaining the projection mask pattern 15 according to a modified example of the third example. The upper portion of FIG. 15 shows another configuration of the projection mask pattern. The projection mask pattern 15 illustrated in the upper portion of FIG. 15 is obtained by randomly arranging the transmission regions 151A formed in the prescribed pattern illustrated in FIG. 12 in each column. The laser irradiation device 10 radiates the laser beam 14 via the projection mask pattern 15 illustrated in the upper portion of FIG. 15.

The lower portion of FIG. 15 is a graph showing the number of irradiations of the laser beam 14 in the portion that becomes the channel region (the portion to be the channel region) when the laser beam 14 is radiated using the projection mask pattern 15 including the transmission regions 151A illustrated in the upper portion of FIG. 15. Also, the lower portion of FIG. 15 shows the number of irradiations when the region that becomes the channel region of the thin film transistor 20 is irradiated with the laser beam 14 using the transmission regions of all the columns (twenty columns in the example of the upper portion of FIG. 15) included in the projection mask pattern 15. In the graph of the lower portion of FIG. 15, a horizontal axis is an irradiation position of the laser beam in the portion that becomes the channel region, and a vertical axis is the number of irradiations of the laser beam 14.

As shown in the lower portion of FIG. 15, the number of irradiations of the laser beam 14 transmitted through the projection mask pattern 15 including the transmission regions 151A in the region that becomes the channel region (the portion to be the channel region) is the same in the irradiation range of 5.2 μm shown in the lower portion of FIG. 15. As illustrated in the lower portion of FIG. 15, the number of irradiations of the laser beam 14 transmitted through the projection mask pattern 15 illustrated in the upper portion of FIG. 15 is the same in the irradiation range with a width of 5.2 μm. Since the number of irradiations is the same, energy of the laser beam 14 radiated to the region that becomes the channel region (the region included in the irradiation range having a width of 5.2 μm) is made uniform.

As described above, in the third example, the transmission regions 151A in the projection mask pattern 15 are formed in the prescribed pattern. Therefore, the transmission regions 151A in the projection mask pattern 15 can be easily formed.

### Fourth Example

A fourth example is an example of when laser annealing is performed using one projection lens 18 instead of the microlens array 13.

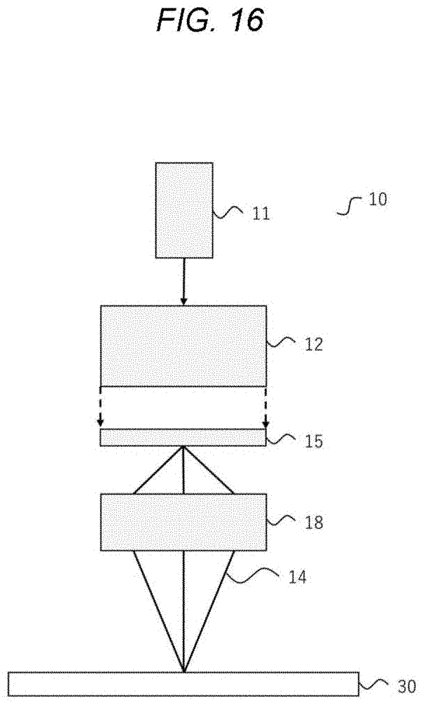

FIG. 16 is a diagram showing a configuration of the laser irradiation device 10 according to a fourth example. As shown in FIG. 16, the laser irradiation device 10 according to the fourth example includes a laser light source 11, a coupling optical system 12, a projection mask pattern 15, and a projection lens 18. Further, since the laser light source 11 and the coupling optical system 12 have the same configuration as the laser light source 11 and the coupling optical system 12 in the first example shown in FIG. 1, a detailed description therefor will be omitted. Also, since the projection mask pattern has the same configuration as the projection mask pattern in the first example, a detailed description therefor will be omitted.

In the fourth example, the projection mask pattern 15 is, for example, the projection mask pattern 15 illustrated in FIG. 12, the upper portion of FIG. 14, and the upper portion of FIG. 15. However, since the mask pattern of the projection mask pattern 15 is converted by a magnification of an optical system of the projection lens 18, it may be different in shape (area or size) from the projection mask pattern illustrated in FIGS. 6 and 7. The laser beam is transmitted through the transmission region 151A (transmission region) of the projection mask pattern 15 and is radiated to a prescribed region of the amorphous silicon thin film 21 via the projection lens 18. As a result, the prescribed region of the amorphous silicon thin film 21 provided on the entire surface of the substrate 30 is instantaneously heated and melted, and a part (the prescribed region) of the amorphous silicon thin film 21 becomes the polysilicon thin film 22.

Also in the fourth example, the laser irradiation device 10 radiates the laser beam 14 at a prescribed cycle, moves the substrate 30 at a time when the laser beam 14 is not radiated, and irradiates a prescribed region of the next amorphous silicon thin film 21 with the laser beam 14. Also, in the fourth example, as shown in FIG. 3, the amorphous silicon thin film 21 is disposed on the entire surface of the substrate 30. Then, the laser irradiation device 10 irradiates the prescribed region of the amorphous silicon thin film 21 disposed on the substrate 30 with the laser beam 14 at a prescribed cycle.

When the projection lens 18 is used, the laser beam 14 is converted by the magnification of the optical system of the projection lens 18. That is, a pattern of the projection mask pattern 15 is converted by the magnification of the optical system of the projection lens 18, and the prescribed region of the amorphous silicon thin film 21 formed (deposited) on the substrate 30 is laser-annealed.

That is, the mask pattern of the projection mask pattern 15 is converted by the magnification of the optical system of the projection lens 18, and the prescribed region of the amorphous silicon thin film 21 formed (deposited) on the substrate 30 is laser-annealed. For example, when the magnification of the optical system of the projection lens 18 is about twice, the mask pattern of the projection mask pattern 15 is multiplied by about ½(0.5), and the prescribed region of the substrate 30 is laser-annealed. Also, the magnification of the optical system of the projection lens 18 is not limited to about twice and may be any magnification. In the mask pattern of the projection mask pattern 15, the prescribed region on the substrate 30 is laser-annealed in accordance with the magnification of the optical system of the projection lens 18. For example, when the magnification of the optical system of the projection lens 18 is four times, the mask pattern of the projection mask pattern 15 is multiplied by about ¼ (0.25), and the prescribed region of the amorphous silicon thin film 21 formed (deposited) on the substrate 30 is laser-annealed.

Further, when the projection lens 18 forms an inverted image, a reduced image of the projection mask pattern 15 projected on the amorphous silicon thin film 21 formed (deposited) on the substrate 30 is a pattern rotated 180 degrees about an optical axis of the projection lens 18. On the other hand, when the projection lens 18 forms an erect image, a reduced image of the projection mask pattern 15 projected on the amorphous silicon thin film 21 formed (deposited) on the substrate 30 remains the same as the projection mask pattern 15.

As described above, in the fourth example, even when laser annealing is performed using one projection lens 18, characteristics of the thin film transistors 20 adjacent to each other are different from each other in the whole substrate 30, whereby a difference in display (for example, a difference in shades of color or the like) due to a difference in the characteristics does not appear in a “line shape.” For that reason, display unevenness does not become a “streak” on a liquid crystal screen, and the display unevenness can be prevented from being highlighted.

Further, when there are descriptions such as “vertical,” “parallel,” “plane,” “orthogonal,” etc., these descriptions do not indicate strict meanings. That is, the terms “vertical”, “parallel”, “plane”, and “orthogonal” allow tolerances and errors in designing, manufacturing, or the like, and mean “substantially vertical,” “substantially parallel,” “substantially plane,” and “substantially orthogonal.” In addition, the tolerances or errors are meant to have units within a range not departing from configurations, operations, and desired effects.

Also, when there are descriptions such as dimensions or sizes in appearance being “same,” “equal,” “different,” and the like, these descriptions do not indicate strict meanings. That is, the terms “same,” “equal,” and “different” allow tolerances and errors in designing, manufacturing, or the like, and mean “substantially the same,” “substantially equal,” and “substantially different.” In addition, the tolerances or errors are meant to have units within a range not departing from configurations, operations, and desired effects.

Although this disclosure has been described on the basis of the drawings and examples, it should be noted that those skilled in the art can easily make various changes and modifications on the basis of the disclosure. Therefore, these changes and modifications are included in the scope of the disclosure. For example, functions included in each means, each step, and the like can be rearranged so as not to be logically inconsistent, and a plurality of means, steps, and the like can be combined into one or can be divided. Also, configurations described in the above examples may be combined as appropriate.

What is claimed is:

1. A laser irradiation device comprising:
a light source that generates a laser beam;
a projection lens that irradiates a prescribed region of an amorphous silicon thin film deposited on a substrate with the laser beam; and
a projection mask pattern disposed on the projection lens and includes a rectangular transmission region transmitting the laser beam in a prescribed projection pattern,
wherein a short side of the rectangular transmission region has a length that causes irradiation energy of the laser beam transmitted through the projection mask pattern to become substantially uniform in the prescribed region.

2. The laser irradiation device according to claim 1,
wherein the projection lens irradiates a plurality of prescribed regions on the substrate moving in a prescribed direction with the laser beam via the projection mask pattern, and
the projection mask pattern is configured such that at least transmission regions adjacent to each other in one column orthogonal to a movement direction have different irradiation ranges on the prescribed regions from each other.

3. The laser irradiation device according to claim 1, wherein the projection lens irradiates each prescribed region with the laser beam using a plurality of transmission regions.

4. The laser irradiation device according to claim 2, wherein the projection lens irradiates one of the prescribed regions with the laser beam using a plurality of transmission regions.

5. The laser irradiation device according to claim 2, wherein the projection mask pattern is configured such that at least transmission regions adjacent to each other in one row in the movement direction have different irradiation ranges on the prescribed regions from each other.

6. The laser irradiation device according to claim 4, wherein the projection mask pattern is configured such that at least transmission regions adjacent to each other in one row in the movement direction have different irradiation ranges on the prescribed regions from each other.

7. The laser irradiation device according to claim 1, wherein the projection mask pattern is configured such that a width or a size of the transmission region is determined on the basis of energy of the laser beam in the prescribed region.

8. The laser irradiation device according to claim 1,
wherein the projection lens is a plurality of microlenses included in a microlens array that can separate the laser beam, and
each of a plurality of openings on masks included in the projection mask pattern corresponds to one of the plurality of microlenses.

9. A laser irradiation method comprising:
a generation step of generating a laser beam;
a transmission step of transmitting the laser beam using a prescribed projection pattern via a projection mask pattern disposed on a projection lens and includes a rectangular transmission region transmitting the laser beam in the prescribed projection pattern; and
an irradiation step of irradiating a prescribed region of an amorphous silicon thin film deposited on a substrate with the laser beam transmitted through the prescribed projection pattern,
wherein a short side of the rectangular transmission region has a length that causes irradiation energy of the laser beam transmitted through the projection mask pattern to become substantially uniform in the prescribed region.

10. A non-transitory computer-readable storage medium storing a program,
wherein the program causes a computer to execute:
a generation function of generating a laser beam;
a transmission function of transmitting the laser beam using a prescribed projection pattern via a projection mask pattern disposed on a projection lens and includes a rectangular transmission region transmitting the laser beam in the prescribed projection pattern; and
an irradiation function of irradiating a prescribed region of an amorphous silicon thin film deposited on a substrate with the laser beam transmitted through the prescribed projection pattern,
wherein a short side of the rectangular transmission region has a length that causes irradiation energy of the laser beam transmitted through the projection mask pattern to become substantially uniform in the prescribed region.

11. A projection mask disposed on a projection lens which radiates a laser beam generated from a light source,
wherein the projection mask is provided with a rectangular transmission region to irradiate a prescribed region of an amorphous silicon thin film deposited on a substrate moving in a prescribed direction with the laser beam, and
a short side of the rectangular transmission region has a length that causes irradiation energy of the laser beam transmitted through the transmission region to become substantially uniform in the prescribed region.
